(19) United States
(12) Patent Application Publication
(10) Pub. No.: US 2012/0080805 A1
(43) Pub. Date: Apr. 5, 2012

(54) Semiconductor device and method of manufacturing the same

(75) Inventors: Chikako Ohto, Kanagawa (JP); Tatsuya Usami, Kanagawa (JP); Shuji Nagano, Tsukuba (JP); Hideharu Shimizu, Tsukuba (JP); Tatsuya Ohira, Uenohara (JP); Takeshi Kada, Uenohara (JP)

(73) Assignees: Renesas Electronics Corporation, Kawasaki-shi (JP); Taiyo Nippon Sanso Corporation, Tokyo (JP); Tri Chemical Laboratories Inc., Uenohara-shi (JP)

(21) Appl. No.: 13/200,654

(22) Filed: Sep. 28, 2011

(30) Foreign Application Priority Data
Sep. 30, 2010 (JP) 2010-220294

(51) Int. Cl. H01L 23/48; H01L 21/28

(52) U.S. Cl. 257/774; 438/618; 257/E23.011; 257/E21.158

(57) ABSTRACT

A semiconductor device according to the invention includes a first Cu interconnect and a first barrier insulating film. a The first barrier insulating film is provided on the first Cu interconnect, and prevents Cu from being diffused from the first Cu interconnect. In addition, the semiconductor device includes a second Cu interconnect and a second barrier insulating film on the first barrier insulating film. The second barrier insulating film is provided on a first Cu interconnect, and prevents Cu from being diffused from the second Cu interconnect. The first and second barrier insulating films are made of a silicon-based insulating film having a branched alkyl group and a carbon-carbon double bond.

### CROSS-REFERENCE TO RELATED APPLICATIONS

The disclosure of Japanese Patent Application No. 2010-220294, filed on Sep. 30, 2010 including the specification, drawings and abstract is incorporated herein by reference in its entirety.

### BACKGROUND

1. Technical Field

The present invention relates to a semiconductor device and a method of manufacturing the same.

2. Related Art

In silicon semiconductor integrated circuits (hereinafter, referred to as LSIs), formerly aluminum (Al) or an Al alloy has been widely used as a conductive material. With the progress of miniaturization of LSIs, copper (Cu) has been used as a conductive material in order to achieve the reduction in the interconnect resistance and the high reliability of the interconnect. Since Cu is easily diffused into a silicon oxide film, a technique is known in which a barrier insulating film is formed on the upper surface of a Cu interconnect, to thereby prevent Cu from being diffused (see, for example, Japanese Unexamined Patent Publication No. 2007-88495, Japanese Unexamined Patent Publication No. 2009-170872, and Japanese Unexamined Patent Publication No. 2009-182000).

For example, Japanese Unexamined Patent Publication No. 2007-88495 discloses a technique for forming a barrier insulating film having a thickness of 30 to 150 nm so as to cover the upper portion of the Cu interconnect, and forming a SiOCH film having a thickness of 200 to 500 nm as an insulating interlayer on the barrier insulating film.

In addition, Japanese Unexamined Patent Publication No. 2009-170872 discloses a technique for forming a silicon carbide-based barrier layer including a silicon-carbon bond or a carbon-carbon bond such as a carbon-carbon single bond (C—C), a carbon-carbon double bond (C═C), and a carbon-carbon triple bond (C≡C), or a combination thereof. Thereby, it is possible to provide a method of forming a dielectric barrier having a low dielectric constant, an improved etching resistance, and an excellent barrier performance.

Further, Japanese Unexamined Patent Publication No. 2009-182000 discloses a technique for making the density of at least a portion of a second insulating barrier film higher by performing high-density treatment. In this way, even when the second insulating barrier film becomes thin, it is possible to prevent water from infiltrating from a low-dielectric-constant insulating film provided on the second insulating barrier film, and to obtain an interconnect structure having a low effective relative dielectric constant while preventing surface oxidation of a copper film provided below the second insulating barrier film, and sufficiently securing the electro migration (EM) resistance of an interconnect and the time dependent dielectric breakdown (TDDB) lifetime between interconnects.

The present inventors have now discovered a problem in the related art disclosed in Japanese Unexamined Patent Publication No. 2009-182000, which the higher density of the barrier insulating film cause the higher dielectric constant of that. For this reason, there has been a problem that the effective dielectric constant can be decreased only if a high-density layer makes very thin. However, in the technique disclosed in Japanese Unexamined Patent Publication No. 2009-182000, since a high-density layer is formed by high-density treatment on a SiCO film formed on a Cu film through helium plasma treatment, it has been very difficult to control the thickness of the high-density layer.

The present inventors also have discovered a problem water permeability of the barrier insulating film formed by 4MS (tetramethylsilane) is high. Therefore, we have recognized that problems such as EM and TDDB cannot be sufficiently solved by the barrier insulating film formed by 4MS.

Accordingly, it has been discovered that the techniques mentioned above has made it impossible to sufficiently improve the reliability of a semiconductor device having a fine interconnect.

### SUMMARY

In one embodiment, there is provided a semiconductor device including:

a metal interconnect; and

a barrier insulating film provided over the metal interconnect, which prevents a metal from being diffused from the metal interconnect,

wherein the barrier insulating film is made of a silicon-based insulating film having a branched alkyl group and a carbon-carbon double bond.

In another embodiment, there is provided a method of manufacturing a semiconductor device, including:

forming a metal interconnect; and

forming a barrier insulating film on the metal interconnect, which prevents a metal from being diffused from the metal interconnect,

wherein forming the barrier insulating film includes forming a silicon-based insulating film having a branched alkyl group and a carbon-carbon double bond.

According to the invention, since the barrier insulating film is made of a silicon-based insulating film having a branched alkyl group and a carbon-carbon double bond, it is possible to secure the EM resistance and the TDDB lifetime between interconnects by suppressing the water permeability while reducing the effective relative dielectric constant. Therefore, it is possible to improve the reliability of a semiconductor device having a fine interconnect.

According to the invention, it is possible to improve the reliability of a semiconductor device having a fine interconnect.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view schematically illustrating a semiconductor device according to an embodiment.

FIGS. 2A to 2C are diagrams for explaining an example of a method of manufacturing the semiconductor device according to the embodiment.

FIG. 3 is a diagram for explaining an example of the method of manufacturing the semiconductor device according to the embodiment.

FIG. 4 is a diagram for explaining an example of the method of manufacturing the semiconductor device according to the embodiment.

FIG. 5 is a schematic cross-sectional view illustrating a structure used in an example.

FIGS. 6A to 6C are diagrams illustrating FT-IR charts before and after moisture absorption tests are performed using a barrier insulating film of the invention.

FIGS. 7A to 7C are diagrams illustrating FT-IR charts before and after the moisture absorption tests are performed using the barrier insulating film of the invention.

FIG. 8 is a diagram illustrating an FT-IR chart before and after the moisture absorption tests are performed using a barrier insulating film in the related art.

FIG. 9 is a diagram illustrating an FT-IR result immediately after the barrier insulating film of the invention and the barrier insulating film in the related art are respectively formed.

FIGS. 10A and 10B are diagrams illustrating an FT-IR chart before and after the moisture absorption tests are performed using the barrier insulating film of the invention and the barrier insulating film in the related art, respectively.

FIGS. 11A to 11C are diagrams in which bonding changes after PCT tests are quantified in the barrier insulating film of the invention and the barrier insulating film in the related art.

FIG. 12 is a diagram illustrating an oxygen profile in the depth direction through XPS of the barrier insulating film of the invention and the barrier insulating film in the related art.

FIGS. 13A and 13B are diagrams illustrating a result of examination of the difference in activation energy for forming a C—CH₃ bond according to the difference in raw material gas.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and signs and descriptions thereof will not be repeated.

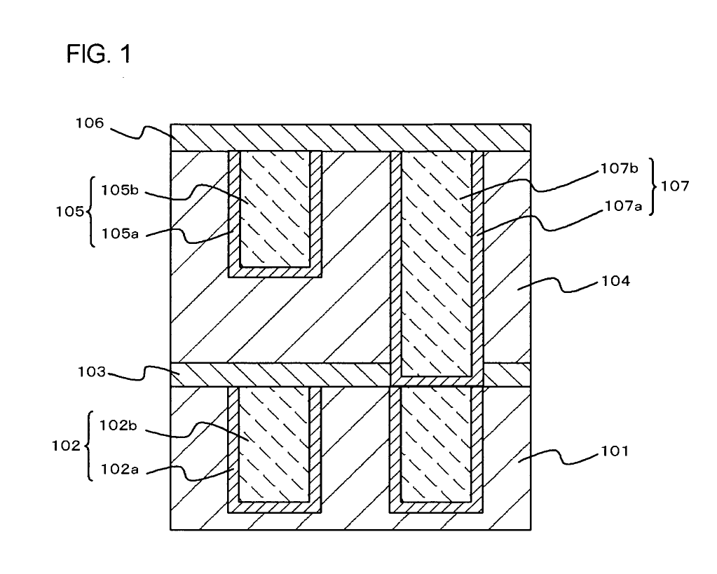

FIG. 1 is a cross-sectional view schematically illustrating a semiconductor device according to the embodiment. The semiconductor device includes a first Cu (copper) interconnect 102 and a first barrier insulating film 103. The first barrier insulating film 103 is provided on the first Cu interconnect 102, and prevents Cu from being diffused from the first Cu interconnect 102. In addition, the semiconductor device includes a second Cu interconnect 105 and a second barrier insulating film 106 on the first barrier insulating film 103. The second barrier insulating film 106 is provided on the first Cu interconnect 105, and prevents Cu from being diffused from the second Cu interconnect 105. The first and second barrier insulating films 103 and 106 are made of a silicon-based insulating film having a branched alkyl group and a carbon-carbon double bond.

Hereinafter, the semiconductor device of the embodiment will be described in detail. The semiconductor device of the embodiment includes a lower-layer film in which transistors are formed on a semiconductor substrate (not shown), and a first insulating interlayer 101 is formed on the lower-layer film. In addition, the first barrier insulating film 103, a second insulating interlayer 104, and the second barrier insulating film 106 are laminated on the first insulating interlayer 101 in this order.

The first and second insulating interlayers 101 and 104 are all low dielectric constant films having a relative dielectric constant lower than the relative dielectric constant (k=3.9 to 4.5) of a silicon oxide film. The thicknesses of the first and second insulating interlayers 101 and 104 are larger than that of the first barrier insulating film 103, and can be set to, for example, 200 to 500 nm. The first and second insulating interlayers 101 and 104 can be formed as, for example, a SiCH film, a SiCNH film, a SiCOH and a SiCONH film.

Trenches are formed in each of the first insulating interlayers 101 and the second insulating interlayer 104. A first barrier metal film 102a and a first Cu film 102b are formed in the inside of the trench formed in the first insulating interlayer 101, which constitute the first Cu interconnect 102. In addition, a second barrier metal film 105a and a second Cu film 105b are formed in the inside of the trench formed in the second insulating interlayer 104, which constitute the second Cu interconnect 105. Further, via 107 is formed in the second insulating interlayer 104. Via 107 passes through the first barrier insulating film 103, and is connected to the first Cu interconnect 102 formed in the first insulating interlayer 101. A via hole is formed in the second insulating interlayer, and a third barrier metal film 107a and a third Cu film 107b are formed in the inside thereof to give the via 107.

The first, second, and third barrier metal films 102a, 105a, and 107a are respectively films containing tantalum (Ta) or titanium (Ti) as a main metal, and can be formed of, for example, Ta, TaN, TiN or the like. The first, second, and third barrier metal films 102a, 105a, and 107a may be a single layer, and may be a layer in which two or more different types of layers are laminated. Thereby, it is possible to prevent Cu in the first Cu interconnect 102 from being diffused to the first insulating interlayer 101. In addition, it is possible to prevent Cu in the second Cu interconnect 105 and the via 107 from being diffused to the second insulating interlayer 104.

The first, second, and third Cu films 102b, 105a, and 107a may be a film containing Cu as a main component, may be a film made of only Cu, and may be a Cu alloy containing Cu and other metals (Al, Mn, Mg and the like).

The first Cu film 102b exposed to the surface of the first insulating interlayer 101, and the second and third Cu films 105b and 107b exposed to the surface of the second insulating interlayer 104 may be covered with a cap metal film (not shown). The cap metal film can be formed of a film containing, for example, cobalt (Co), tungsten (W) or the like as a main component.

The first and second barrier insulating films 103 and 106 may be a silicon-based insulating film having a branched alkyl group and a carbon-carbon double bond, and can be set to be 1 to 100 nm in thickness. The branched alkyl group is preferably a substituent having a C—CH₃ bond. The branched alkyl group and the carbon-carbon double bond can be confirmed by examining infrared absorption with infrared spectroscopy.

The relative dielectric constant k of the first and second barrier insulating films 103 and 106 can be set to 4.0 or less, more preferably 3.5 or less, and much more preferably 3.0 or less. In addition, the first and second barrier insulating films 103 and 106 make possible to decrease the water permeability while maintaining such a low dielectric constant. For example, it is possible to maintain the low water permeability even under the conditions of the temperature of 105 to 143° C., the humidity of 75 to 100%, the pressure of 0.02 to 0.2 MPa, and 100 hours.

The first and second barrier insulating films 103 and 106 may be a silicon-based insulating film containing silicon (Si), and can be formed of any of a SiCH film, a SiCNH film, a SiCOH film, a SiCONH film or the like. Nitrogen atom (N) or oxygen atom (O) is contained in the first and second barrier insulating films 103 and 106 like the SiCNH film, the SiCOH film and the SiCONH film, thereby allowing the leakage current to be reduced. In addition, nitrogen atom (N) is contained in the first and second barrier insulating films 103 and 106 like the SiCNH film and the SiCONH film, thereby allowing the ratio of the dry etching selectivity to the upper-layer insulating interlayer such as the second insulating interlayer 104 to be increased. In addition, oxygen atoms (O) are added to the first and second barrier insulating films 103 and 106 like the SiCOH film and the SiCONH film, thereby allowing the adhesion to the upper-layer insulating interlayer such as the second insulating interlayer 104 to be improved.

An insulating film (for example, SiCN film or the like) made of a material different from that of the first insulating interlayer 101 and the first barrier insulating film 103 may be provided between the first insulating interlayer 101 and the first barrier insulating film 103. In addition, similarly, an insulating film made of a material different from that of the second insulating interlayer 104 and the second barrier insulating film 106 can also be provided between the second insulating interlayer 104 and the second barrier insulating film 106. In this way, it is possible to improve the adhesion between the first insulating interlayer 101 and the first barrier insulating film 103, or between the second insulating interlayer 104 and the second barrier insulating film 106.

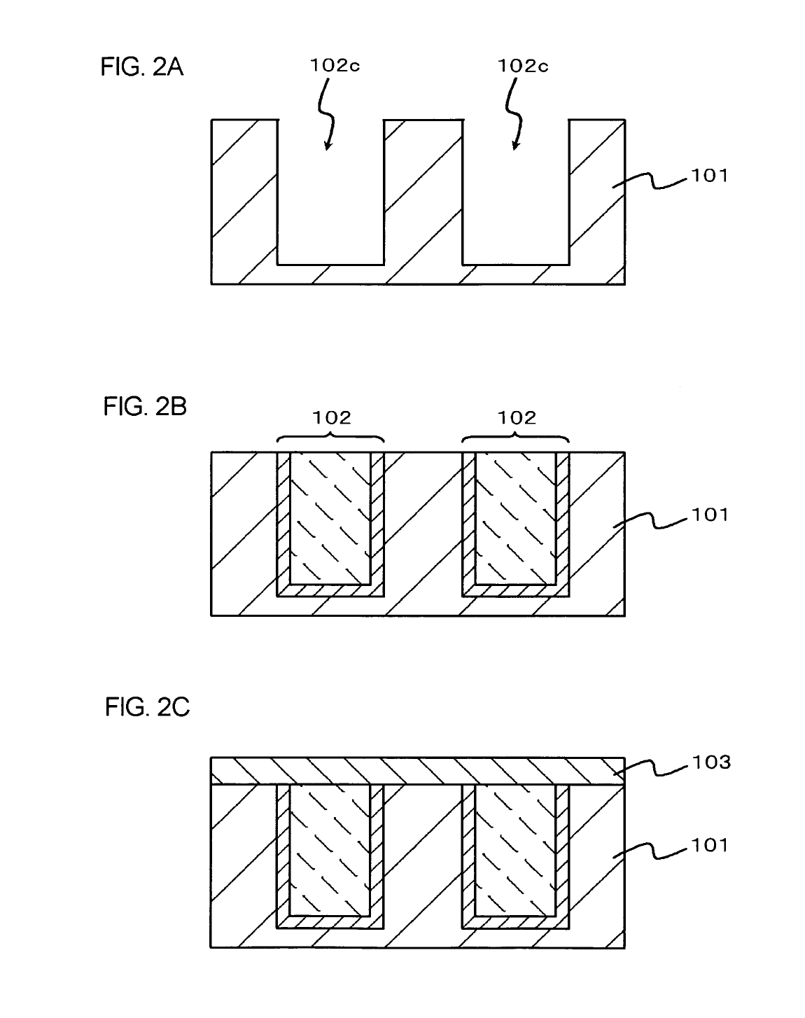

Subsequently, an example of a method of manufacturing the semiconductor device of the embodiment will be described with reference to FIGS. 2A to 2C to FIG. 4. First, an element such as a transistor is formed on the semiconductor substrate such as a silicon substrate, and an underlying layer is created (not shown). Next, after the first insulating interlayer 101 is formed on the underlying layer by a plasma chemical vapor deposition (CVD) method, an trench 102c is formed in the first insulating interlayer 101 with a photolithography technique (FIG. 2A).

Subsequently, the first barrier metal film 102a is formed in the trench 102c by a sputtering method or a CVD method, and then first Cu film 102b is buried by a sputtering method, a CVD method or a plating method. The first barrier metal film 102a and the first Cu film 102b is removed on the first insulating interlayer 101 by a chemical mechanical polishing (CMP) method (FIG. 2B) to give the first Cu interconnect 102.

Subsequently, the first barrier insulating film 103 is formed so as to cover the first insulating interlayer 101 and the first interconnect 102 exposed from the first insulating interlayer 101 (FIG. 2C). The first barrier insulating film 103 can be formed by a plasma CVD method, and a compound of the following general formula (1) can be used as raw material gas.

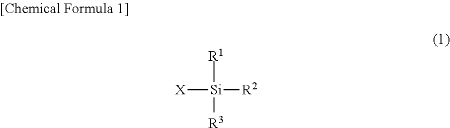

In general formula (1), R¹ is a branched-chain alkyl group having a carbon number of 3 to 6, R² and R³ are an unsaturated hydrocarbon group or a saturated hydrocarbon group, and X is any one of a silicon atom to which an unsaturated hydrocarbon group or a saturated hydrocarbon group is bonded; a hydrogen atom; a nitrogen atom to which any one of an unsaturated hydrocarbon group and a saturated hydrocarbon group is bonded; an unsaturated hydrocarbon group; or a saturated hydrocarbon group, wherein each of the unsaturated hydrocarbon group and the saturated hydrocarbon group is any one of a vinyl group, an allyl group, and an alkyl group having a carbon number of 1 to 6, and R¹, R², R³ and X may be equal to or different from each other.

Specifically, in general formula (1), R¹ is preferably a substituent having a C—CH₃ bond, more preferably any one of an isobutyl group, a sec-butyl group, a tert-butyl group, an isopentyl group and an isohexyl group, and particularly preferable an isobutyl group. In addition, X is more preferably a chain-like or branched alkyl group having a carbon number of 1 to 6.

R² is also preferably a branched-chain alkyl group having a carbon number of 3 to 6. The lower water permeability can be obtained by increasing the number of isobutyl groups bonded to one Si atom. Therefore, any two or more of X, R¹, R² and R³ preferably have an isobutyl group. Further, in general formula (1), X is preferably an unsaturated hydrocarbon group or a saturated hydrocarbon group. In this way, it is possible to form the barrier insulating film made of a SiCH film. For example, butyl silane such as diisobutyl dimethyl silane, isobutyl trimethoxy silane, triisobutyl methyl silane, and tetramethyl isobutyl silane can be used as raw material gas. It is preferable that substituent groups bonding to one Si atom include more branched-chain alkyl groups (particularly, isobutyl groups).

Ammonia gas may be added to a compound of general formula (1) in which X is an unsaturated hydrocarbon group or a saturated hydrocarbon group. In this way, the barrier insulating film made of a SiCNH film can be formed. CO₂, CO or O₂ gas may be added to the compound in which X is an unsaturated hydrocarbon group or a saturated hydrocarbon group to form a SiCOH film, and N₂O or NO gas or the like may be added thereto to form a SiCONH film.

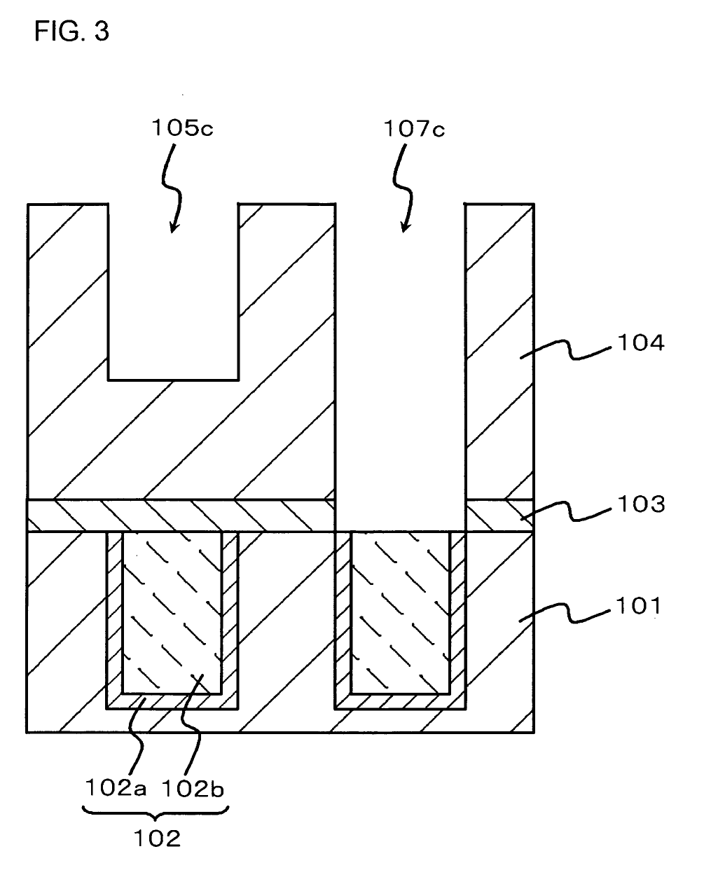

Subsequently, the second insulating interlayer 104 is formed on the first barrier insulating film 103 by a plasma CVD method, and then an trench 105c and a via hole 107c are formed in the second insulating interlayer 104 with a photolithography technique (FIG. 3).

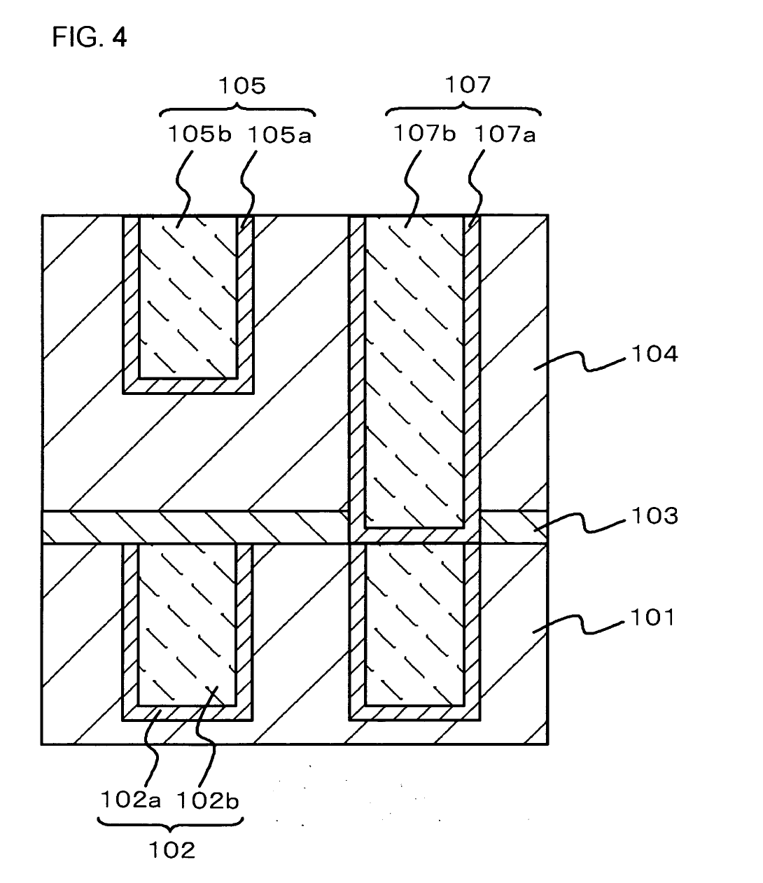

Thereafter, the second and third barrier metal films 105a and 107a are simultaneously formed in the trench 105c and the via hole 107c by a sputtering method or a CVD method, and then the second and third Cu films 105b and 107b are simultaneously buried by a sputtering method, a CVD method or a plating method. The second Cu film 105b, the third Cu film 107b, the second barrier metal film 105a and the third barrier metal film 107a on the second insulating interlayer 104 are removed by a chemical mechanical polishing (CMP) method (FIG. 4) to give the second interconnect 105 and via 107.

Next, the second barrier insulating film 106 is formed by the similar method as that in the first barrier insulating film 103, and the structure of FIG. 1 is created. The structure of FIG. 1 may be further created using the structure shown in FIG. 1 as an underlying film. Thereafter, the semiconductor device is completed by an arbitrary method.

Subsequently, the operations and effects of the embodiment will be described. According to the semiconductor device of the embodiment, the first and second barrier insulating films 103 and 106 are made of a silicon-based insulating film having a branched alkyl group and a carbon-carbon double bond, and thus water permeability is suppressed while reducing the effective relative dielectric constant, thereby allowing the EM resistance and the TDDB lifetime between interconnects to be secured. Therefore, it is possible to improve reliability of the semiconductor device having a fine interconnect.

It is considered that carbon of a carbon-carbon double bond and a branched alkyl group in the barrier insulating film made of a silicon-based insulating film having a branched alkyl group and a carbon-carbon double bond react with water, and are oxidized to form a C═O bond or the like, thereby trapping water molecules (H₂O). In this way, it is assumed that water does not permeate to the lower-layer Cu interconnects, and copper oxide is not generated. Therefore, if the barrier insulating film has a carbon-carbon double bond and a branched alkyl group (particularly, a C—CH₃ bond), it is considered to be capable of suppressing (blocking moisture absorption) the water permeability even in the case where the density of the barrier insulating film is not very high.

For example, the barrier insulating film is formed using diisobutyl dimethylsilane (DiBDMS) as the first and second barrier insulating films 103 and 106, thereby allowing the water permeability of the film to be decreased. For this reason, oxidation of the first, second, and third Cu films 102b, 105b, and 107b is suppressed, thereby allowing the Cu oxide film not to be generated.

In the structure of the embodiment, it is preferable to form a SiC(H) film or a SiCN(H) film including a carbon-carbon double bond and a branched alkyl group (particularly, C—CH₃ bond) as the barrier insulating film, and to form a SiCOH or SiCONH film or the like thereon as an insulating interlayer. In this way, since the diffusion of water (oxygen) can be reliably blocked, it is possible to more effectively reduce both the relative dielectric constant and the water permeability of the barrier insulating film.

As described above, although the embodiment of the invention has been set forth with reference to the drawings, it is merely illustrative of the invention, and various configurations other than those stated above can be adopted.

For example, in the embodiment, although the Cu interconnect has been described as a metal interconnect by way of example, the embodiment is not limited to the Cu interconnect, and it is possible to obtain the effect of the invention even in the semiconductor device having an aluminum (Al) interconnect or the like.

### EXAMPLE

### MANUFACTURING EXAMPLE

The structure of FIG. 1 was created by the method of FIGS. 2A to 2C to FIG. 4. First, a porous SiCOH film (k=2.5) was formed as the first and second insulating interlayers 101 and 104. A SiCH film having a relative dielectric constant of 3.5 and a thickness of 30 nm was formed as the first and second barrier insulating films 103 and 106 by performing a parallel plate type plasma CVD method with diisobutyl dimethylsilane (DiBDMS) expressed by the following chemical formula (2). The second Cu interconnect 105 and the via 107 were formed in the second insulating interlayer 104 by a dual damascene method.

Meanwhile, the CVD growth conditions of the first and second barrier insulating films 103 and 106 were as follows.

<Film Formation Conditions of DiBDMS>

Temperature: 350° C.

Flow rate of DiBDMS: 15 sccm

N₂ gas=0 sccm

He gas=0 sccm

RF frequency: 13.56 MHz

RF power: 700 W

Pressure: 0.47 kPa (3.5 Torr)

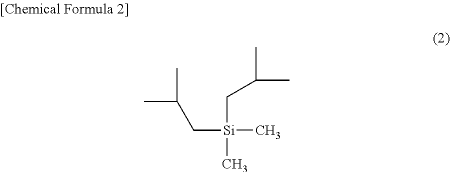

### Evaluation Example 1-1

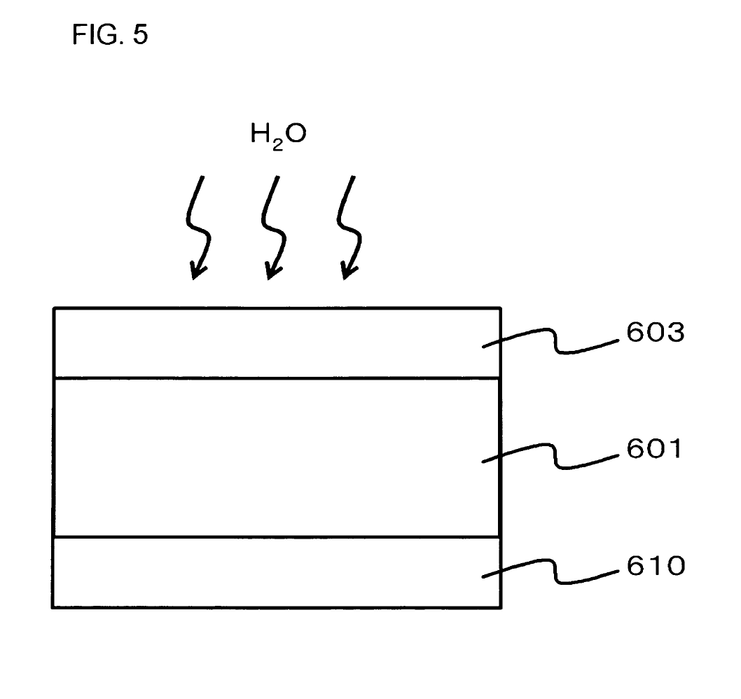

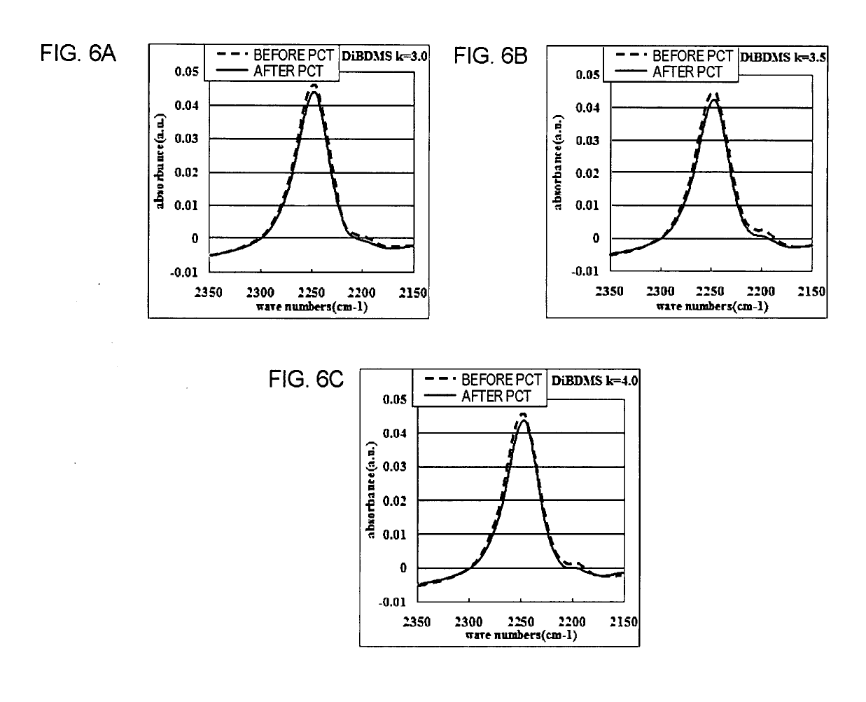

As shown in FIG. 5, a hydrogen silsesquioxane (HSQ) film 601 was formed on a Si substrate 610 having a thickness of 280 nm as an example of an insulating interlayer, and a SiCH film 603 having a thickness of 50 nm was formed thereon as an example of the barrier insulating film by performing a parallel plate type plasma CVD method with DiBDMS as raw material gas. A SiCH film having a relative dielectric constant of 3.5 was formed using the plasma conditions shown in the above-mentioned manufacturing example as the plasma conditions of the SiCH film. In addition, a sample made of a SiCH film of which the relative dielectric constant of the SiCH film is 3.0 and 4.0 was also formed by changing the plasma conditions shown in the above-mentioned manufacturing example in the range of the pressure of 0.2 to 0.67 kPa (1.6 to 5 Torr) and the power of 400 to 650 W. A moisture absorption test was performed by a pressure cooker test (PCT). The PCT conditions were set to an atmospheric pressure of 110 kPa, a temperature of 125° C., a humidity of 100%, and 96 hours. When moisture is absorbed, the Si—H bond of the HSQ film is lost. Consequently, the absorbance of the SiCH film was evaluated by examining whether the Si—H bond of the HSQ film was lost before and after the PCT by the FT-IR. Charts of the obtained FT-IR are shown in FIGS. 6A to 6C. In FIGS. 6A to 6C, the solid line is a chart after the PCT, and the dashed line is a chart before the PCT. FIG. 6A shows a result when the relative dielectric constant of the SiCH film 603 is 3.0, FIG. 6B shows a result when the relative dielectric constant of the SiCH film 603 is 3.5, and FIG. 6C shows a result when the relative dielectric constant of the SiCH film 603 is 4.0. As shown in FIGS. 6A to 6C, the Si-H peak is detected at the wavenumber of 2,250 cm⁻¹. Therefore, the Si—H bond of the HSQ film 601 did not change even after the moisture absorption test, and the SiCH film formed by the DiBDMS was shown to have a very low water permeability.

In Evaluation Example 1-1, when nitrogen gas or helium gas of approximately 5,000 sccm was added to the DiBDMS and the plasma CVD method was performed, or when the DiBDMS was formed by taking a margin of approximately 10% in the range of the pressure of 0.2 to 0.67 kPa (1.6 to 5 Torr) and the power of 400 to 650 W, it was possible to confirm the Si—H bond of the HSQ film 601 after the moisture absorption test. Therefore, it was confirmed that the SiCH film formed by the DiBDMS had a low water permeability.

### Evaluation Example 1-2

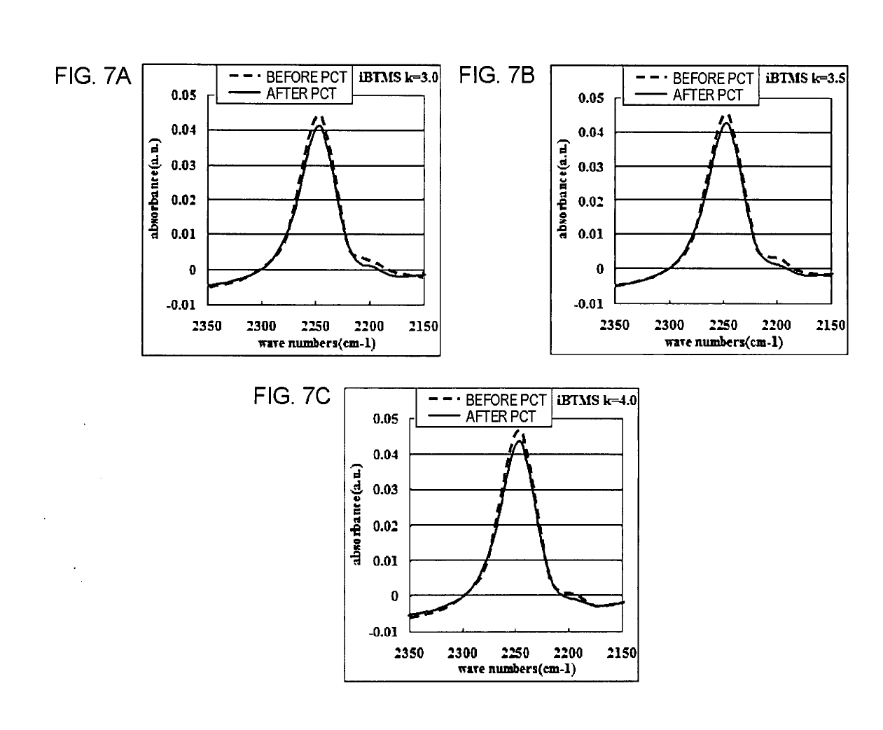

The same conditions with those in evaluation 1-1 were set except that isobutyl trimethoxy silane (iBTMS) was used as raw material gas instead of the DiBDMS, and the plasma conditions were changed to the range of the flow rate of 15 to 30 sccm, the pressure of 0.30 to 0.67 kPa (2.2 to 5 Torr), and the power of 450 to 700 W, to thereby form the SiCH film using a parallel plate type plasma CVD method. The SiCH film having a relative dielectric constant of 3.0, 3.5, and 4.0 was formed. A result of FT-IR is shown in FIGS. 7A to 7C. FIG. 7A shows a result when the relative dielectric constant is 3.0, FIG. 7B shows a result when the relative dielectric constant is 3.5, and FIG. 7C shows a result when the relative dielectric constant is 4.0. As shown in FIGS. 7A to 7C, the Si—H peak is detected at the wavenumber of 2,250 cm⁻¹. Therefore, the SiCH film formed by the iBTMS was also shown to have a very low water permeability.

In Evaluation Example 1-2, when nitrogen gas or helium gas of approximately 5,000 sccm was added to the iBTMS and the plasma CVD method was performed, or when the iBTMS was formed by taking a margin of approximately 10% in the range of the pressure of 0.2 to 0.67 kPa (1.6 to 5 Torr) and the power of 400 to 650 W, it was possible to confirm the Si—H bond of the HSQ film 601 after the moisture absorption test. Therefore, it was confirmed that the SiCH film formed by the iBTMS had a low water permeability.

### Evaluation Example 1-3

The same conditions with those in Evaluation Example 1-1 were set except that 4MS (tetramethylsilane: Si(CH₃)₄) was used as raw material gas instead of the DiBDMS, and the plasma conditions was changed as follows, to thereby form the SiCH film by performing a parallel plate type plasma CVD method. The plasma conditions are shown below. The SiCH film having a relative dielectric constant of 3.6 was obtained.

<Film Formation Conditions of 4MS>

Temperature: 350° C.

Gas flow rate: 30 sccm

N₂ gas: 0 sccm

He gas: 0 sccm

RF frequency: 13.56 MHz

RF power: 600 W

Pressure: 0.4 kPa (3 Torr)

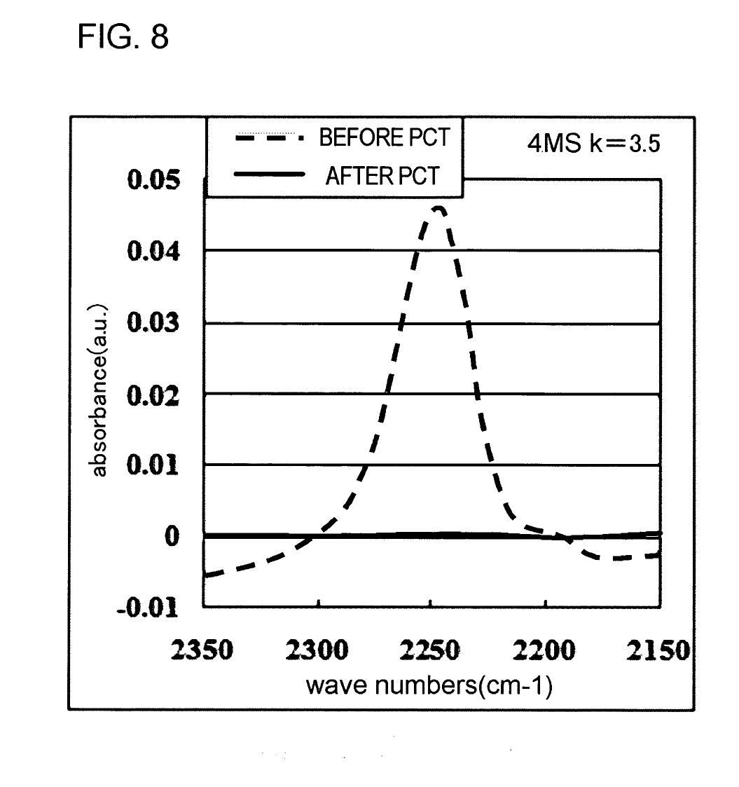

A result of FT-IR is shown in FIG. 8. In FIG. 8, the solid line is a chart after the PCT, and the dashed line is a chart before the PCT. The Si—H bond of the lower-layer HSQ film in the SiCH film formed by the 4MS was not detected after the PCT. Therefore, the SiCH film formed by the 4MS was shown to have a water permeability.

### Evaluation Example 2-1

According to the formation conditions of the barrier insulating film of manufacturing example 1, a single-layer SiCH film having a thickness of 100 nm was formed by the DiBDMS, and the moisture absorption test was performed in the PCT conditions of Evaluation Example 1-1.

### Evaluation Example 2-2

According to the film formation conditions of Evaluation Example 1-3, a single-layer SiCH film having a thickness of 100 nm was formed by the 4MS, and the moisture absorption test was performed in the PCT conditions of Evaluation Example 1-1.

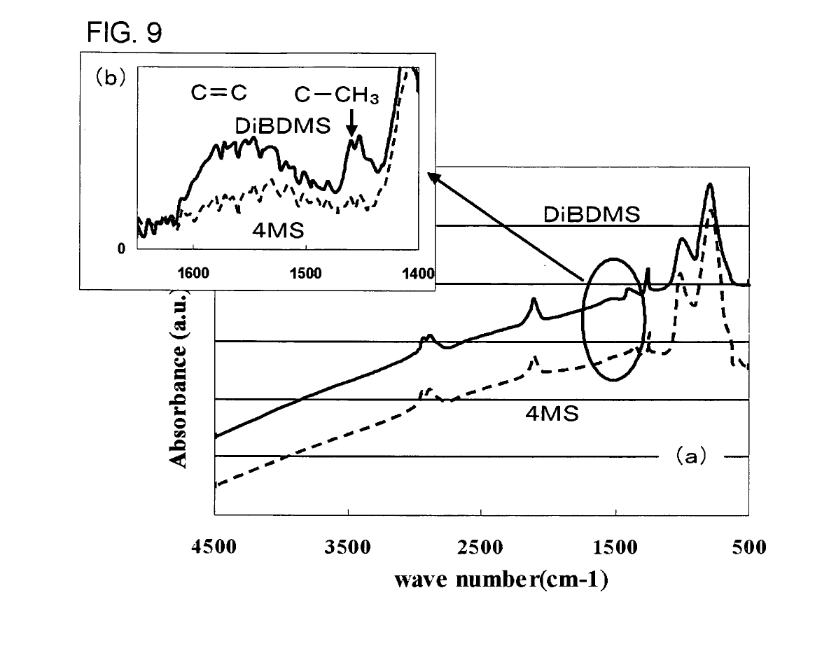

The result of the SiCH film obtained by Evaluation Examples 2-1 and 2-2 before the PCT with FT-IR is shown in FIG. 9(a). FIG. 9(b) is an enlarged view of FIG. 9(a). In FIG. 9, the solid line shows a result of the SiCH film (Evaluation Example 2-1) formed by the DiBDMS, and the dashed line shows a result of the SiCH film (Evaluation Example 2-2) formed by the 4MS. As shown in FIG. 9, the peaks indicating the C═C bond at the wavenumber of about 1,550 cm⁻¹ and the C—CH₃ bond in the vicinity of 1,450 cm⁻¹ were confirmed in the SiCH film (Evaluation Example 2-1) formed by the DiBDMS. On the other hand, the peaks of the C═C bond at the wavenumber of about 1,550 cm⁻¹ and the C—CH₃ bond in the vicinity of about 1,450 cm⁻¹ could not be definitely confirmed in the SiCH film (Evaluation Example 2-2) formed by the 4MS.

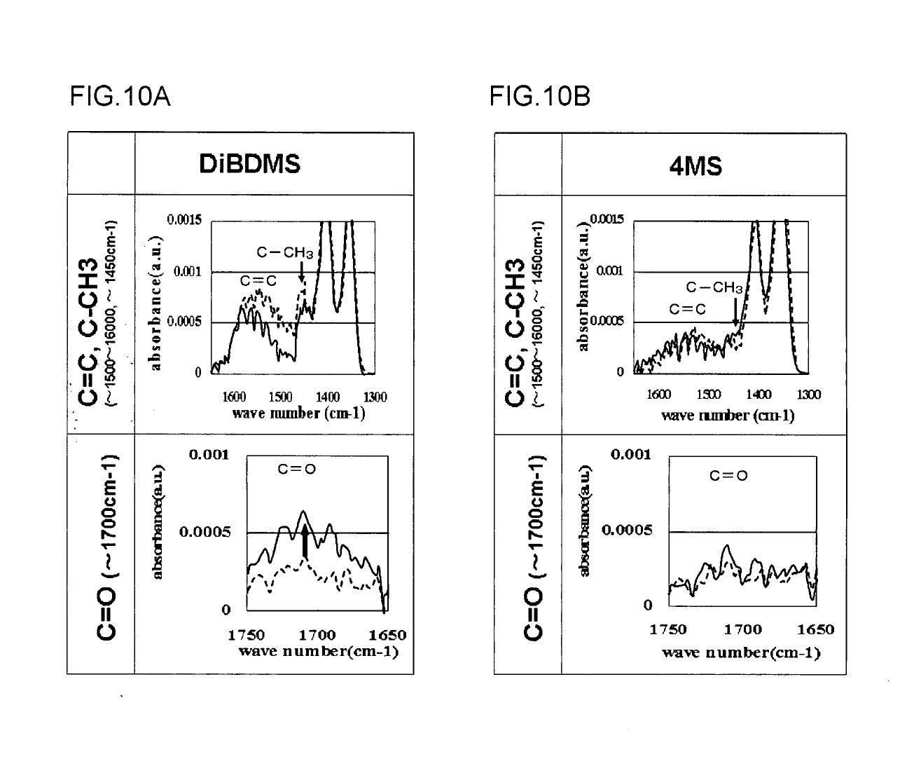

The result of the SiCH film obtained by Evaluation Examples 2-1 and 2-2 before and after the PCT with FT-IR is shown in FIGS. 10A and 10B. In FIGS. 10A and 10B, the solid line is a chart after the PCT, and the dashed line is a chart before the PCT. The result of the SiCH film (Evaluation Example 2-1) formed by the DiBDMS after the PCT was shown that the peak of the C═C bond at the wavenumber of about 1,550 cm⁻¹ and the peak of the C—CH₃ bond at the wavenumber of about 1,450 cm⁻¹ are reduced (FIG. 10A). On the other hand, the result of the SiCH film (Evaluation Example 2-2) formed by the 4MS was shown that the peak of the C═C bond at the wavenumber of about 1,550 cm⁻¹ and the peak of the C—CH₃ bond at the wavenumber of 1,450 cm⁻¹ cannot be definitely confirmed from the beginning. Therefore, the changes between before and after the PCT were not definitely confirmed (FIG. 10B). It could be also confirmed great change in the portion where the infrared absorption of the C═O bond at about 1,700 cm⁻¹. Regarding the SiCH film (Evaluation Example 2-2) formed by the 4MS the change was not definite before and after the PCT (FIG. 10B). On the other hand, regarding the SiCH film (Evaluation Example 2-1) formed by the DiBDMS, an increase in the infrared light absorption indicating the C═O bond at 1,700 cm⁻¹ can be confirmed after the PCT (FIG. 10A).

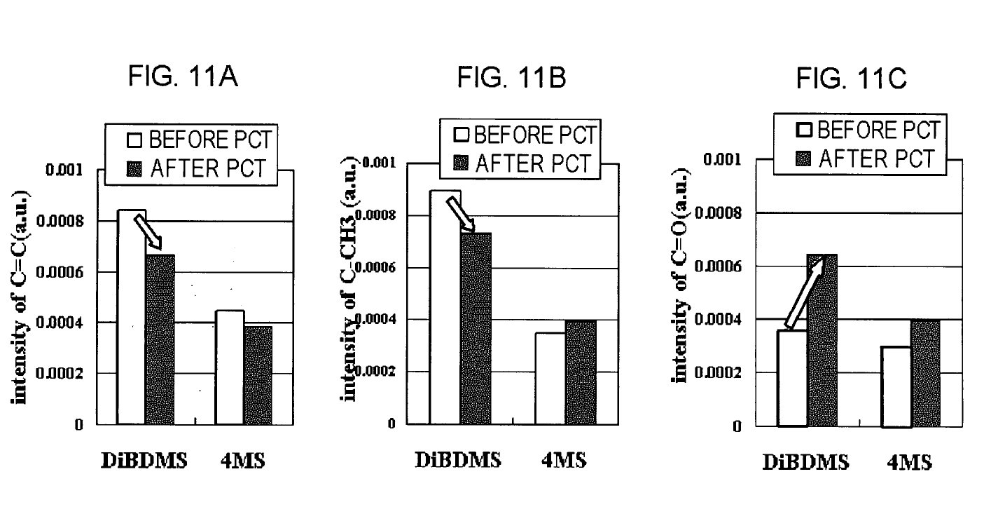

Quantification of the results of FT-IR obtained in Evaluation Example 2-1 and Evaluation Example 2-2 is shown in FIGS. 11A to 11C. FIG. 11A shows a result of the infrared light absorption at about 1,550 cm⁻¹ indicating the presence of the C═C bond. FIG. 11B shows a result of the infrared light absorption in the vicinity of 1,450 cm⁻¹ indicating the presence of the C—CH₃ bond. FIG. 11C shows a result of the infrared light absorption at about 1,700 cm⁻¹ indicating the presence of the C═O bond. The numerical value of 0.005 or less is construed as noise in the view of the accuracy of a measurement device. In the SiCH film (Evaluation Example 2-1) formed by the DiBDMS, it is definitely shown that the number of C═C bonds and the number of C—CH₃ bonds decrease, and the number of C═O bonds increases. On the other hand, in the SiCH film (Evaluation Example 2-2) formed by the 4MS, a relatively large change was not seen. When the relationships between the peals at about 1,550 cm^{-1,} 1,450 cm⁻¹ and 1,700 cm⁻¹ are put together, it is considered that carbon atoms of a portion of C═O and C—CH₃ are partially oxidized to give C═O bonds or the like.

### Measurement of Oxygen Concentration in Film

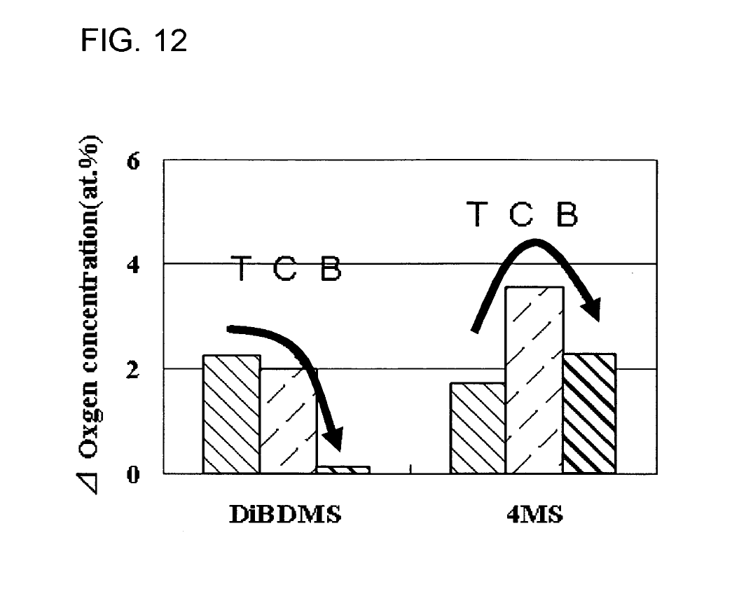

Each of the profiles of the SiCH film formed in Evaluation Examples 2-1 and 2-2 before and after the PCT was confirmed in the depth direction by X-ray photoelectron spectroscopy (XPS). The variation of the oxygen concentration in the film before and after the PCT is shown in FIG. 12. The term “oxygen concentration” here means the concentration of oxygen atoms (unit: atom number % (at. %)) contained in the barrier insulating film. The increase in the oxygen concentration was also confirmed by top (T), center (C), and bottom (B) of the SiCH film (Evaluation Example 2-2) formed by the 4MS. On the other hand, it is assumed that the surface of the SiCH film (Evaluation Example 2-1) formed by the DiBDMS has a large increase for each oxygen layer, but the oxygen concentration drastically decreases as the depth increases, and thus the oxidation does not progress in the inside of the film. That is, it was confirmed that the film having a C═C bond and a C—CH₃ bond in the SiCH film had an effect that water is trapped by oxidation of carbon of the C═C bond and the C—CH₃ bond of SiCH, which causes water to hardly permeate using only the surface layer.

### Confirmatory Experiment of C—CH₃ Bond

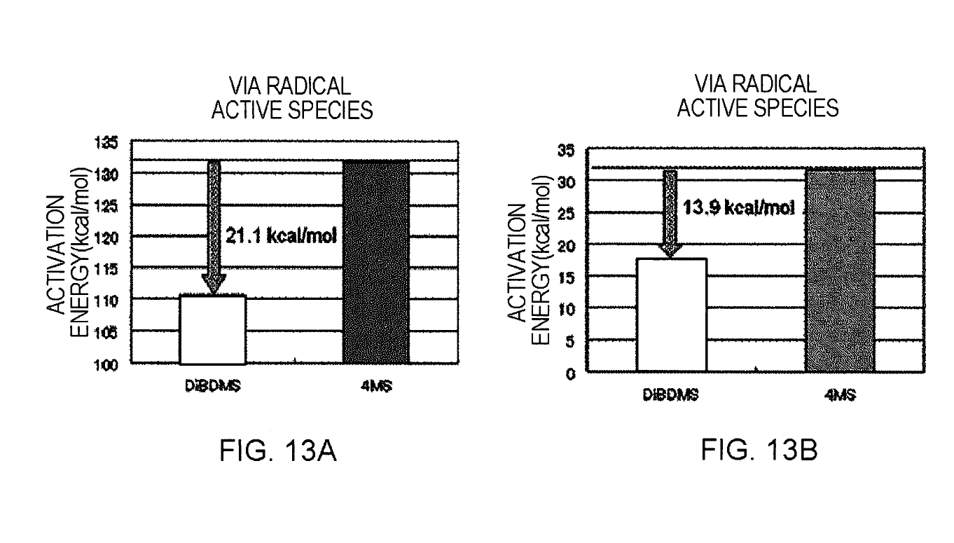

FIGS. 13A and 13B show a result of the SiCH film formed by the 4MS with the infrared light absorption in the vicinity of 1,450 cm⁻¹. It is considered that the result of the 4MS is noise, and the SiCH film formed by the 4MS does not have a C—CH₃ bond. Consequently, this was verified from molecule bond dissociation energy and reaction barrier energy through simulation. GAUSSIANO3 was used as a program, and calculation was performed using a density functional method (B3LYP) as a quantum chemical calculation, and using cc-pVDZ as a predetermined function. It is considered that radical active reactions and ion active reactions occur in order that the 4MS or the DiBDMS is decomposed and re-bonded in a plasma atmosphere, to form a C—CH₃ bond. In initial processes of all the reactions, the ease of reaction was calculated from activation energy (via radical and ion active species), and comparison between reactivity was performed depending on materials from the reaction which most easily forms C—CH₃. As a result, it was clear that the DiBDMS had a low activation barrier for forming the C—CH₃ bond. Therefore, it is considered that use of the DiBDMS as a raw material allows easy formation of the C—CH₃ bond (FIGS. 13A and 13B). Specifically, the result is shown that the DiBDMS is lower than the 4MS by 21.1 kcal/mol via the radical active species (FIG. 13A), and is lower than that by 13.9 kcal/mol via the ion active species (FIG. 13B). That is, it was shown that the C—CH₃ bond was formed in the simulation in the case where the DiBDMS was used as raw material gas, but in the case of the 4MS, the C—CH₃ bond was not formed under the normal plasma conditions. It is considered that a C═C bond is formed mainly via the path of cleaving a side chain of a compound having a C—C bond. That is, regarding a formation of the C═C bond from the C—CH₃ bond, the formation of the C═C bond in the DiBDMS occurs more easily than that in the 4MS. The DiBDMS is an isobutyl group. Therefore, regarding formation of the C═O bond from raw material gas, the DiBDMS is more dominant than the 4MS which does not have a C—C bond, in terms of formation of the C═C bond.

It is apparent that the present invention is not limited to the above embodiment, and may be modified and changed without departing from the scope and spirit of the invention.

What is claimed is:

1. A semiconductor device comprising:
a metal interconnect; and
a barrier insulating film provided over the metal interconnect, which prevents a metal from being diffused from the metal interconnect,
wherein the barrier insulating film is made of a silicon-based insulating film having a branched alkyl group and a carbon-carbon double bond.

2. The semiconductor device according to claim 1, wherein the barrier insulating film is any one of a SiCH film, a SiCNH film, a SiCOH film and a SiCONH film.

3. The semiconductor device according to claim 1, wherein the branched alkyl group is a substituent having a C—CH₃ bond.

4. The semiconductor device according to claim 1, wherein the barrier insulating film is a film formed using a compound of the following general formula (1), 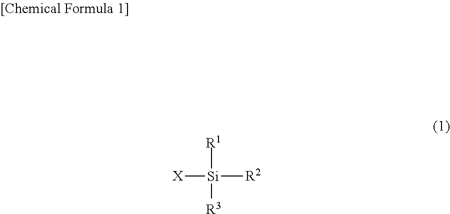
[in general formula (1), R¹ is a branched-chain alkyl group having a carbon number of 3 to 6, R² and R³ are an unsaturated hydrocarbon group or a saturated hydrocarbon group, and X is any one of a silicon atom to which an unsaturated hydrocarbon group or a saturated hydrocarbon group is bonded; a hydrogen atom; a nitrogen atom to which any one of an unsaturated hydrocarbon group and a saturated hydrocarbon group is bonded; or an unsaturated hydrocarbon group or a saturated hydrocarbon group, wherein each of the unsaturated hydrocarbon group and the saturated hydrocarbon group is any one of a vinyl group, an allyl group, and an alkyl group having a carbon number of 1 to 6, and R¹, R², R³ and X may be equal to or different from each other].

5. The semiconductor device according to claim 4, wherein in the general formula (1), R¹ is any one of an isobutyl group, a sec-butyl group, a tert-butyl group, an isopentyl group and an isohexyl group.

6. A method of manufacturing a semiconductor device, comprising:
forming a metal interconnect; and
forming a barrier insulating film on the metal interconnect, which prevents a metal from being diffused from the metal interconnect,
wherein forming the barrier insulating film includes forming a silicon-based insulating film having a branched alkyl group and a carbon-carbon double bond.
